(19) United States
(12) Patent Application Publication
(10) Pub. No.: US 2012/0192934 A1
(43) Pub. Date: Aug. 2, 2012

(54) Nanostructure, Photovoltaic Device, and Method of Fabrication Thereof

(75) Inventors: Zhiyong Fan, Clear Water Bay (HK); Ali Javey, Emeryville, CA (US)

(73) Assignee: The Regents of the University of California, Oakland, CA (US)

(21) Appl. No.: 13/379,455

(22) PCT Filed: Jun. 18, 2010
(86) PCT No.: PCT/US10/39244

§ 371 Date: Apr. 18, 2012

Related U.S. Application Data
(60) Provisional application No. 61/218,974, filed on Jun. 21, 2009.
(60) Provisional application No. 61/251,628, filed on Oct. 14, 2009.

(51) Int. Cl. H01L 31/0352; H01L 31/18; H01L 29/06

(52) U.S. Cl. 136/255; 257/9; 438/95; 257/E29.022; 257/E31.033; 257/E31.015

(57) ABSTRACT

An embodiment of nanostructure includes a conductive substrate; an insulating layer on the conductive substrate, metal nanoparticles, and elongated single crystal nanostructures. The insulating layer includes an array of pore channels. The metal nanoparticles are located at bottoms of the pore channels. The elongated single crystal nanostructures contact the metal nanoparticles and extend out of the pore channels. An embodiment of a photovoltaic device includes the nanostructure and a photoabsorption layer. An embodiment of a method of fabricating a nanostructure includes forming an insulating layer on a conductive substrate. The insulating layer has pore channels arranged in an array. Metal nanoparticles are formed in the pore channels. The metal nanoparticles conductively couple to the conductive layer. Elongated single crystal nanostructures are formed in the pore channels. A portion of the insulating layer is etched away, which leaves the elongated single crystal nanostructures extending out of the insulating layer.

### RELATED APPLICATIONS

This application claims priority to PCT Application PCT/US2010/039244, filed Jun. 18, 2010, which in turn claims priority to U.S. Provisional Application Ser. No. 61/251,628 filed Oct. 14, 2009, and U.S. Provisional Application Ser. No. 61/218,974 filed Jun. 21, 2009, both of which applications are incorporated herein by reference as if fully set forth in their entirety.

### STATEMENT OF GOVERNMENT SUPPORT

This invention was made with government support under Contract No. DE-AC02-05CH11231 awarded by the U.S. Department of Energy. The government has certain rights in this invention.

### BACKGROUND OF THE INVENTION

The present invention relates to the field of nanotechnology and, more particularly, to the field of photovoltaics.

Solar energy represents one of the most abundant and yet least harvested source of renewable energy. In recent years, tremendous progress has been made in developing photovoltaics (PVs) that can be potentially mass employed. Of particular interest to cost-effective solar cells is to utilize novel device structures and materials processing for enabling acceptable efficiencies (e.g., see Law, M. et al., Nature Mater. 4, 455-459 (2005)).

The ability to deposit single-crystalline semiconductors on support substrates is of profound interest for high performance solar cell applications. The most common approach involves epitaxial growth of thin films by using single crystalline substrates as the template. In this approach, the grown material could be either transferred to another substrate by a lift-off or printing process, or remain on the original substrate for fabrication of the solar modules. This epitaxial growth process, while highly useful for efficient PVs, may not be applicable for cost-effective solar modules, especially when compound semiconductors are used. Recently, semiconductor nanowires grown by a vapor-liquid-solid (VLS) process have been shown as a highly promising material system for PV devices (e.g., see Garnett, E. C. et al., J. Am. Chem. Soc. 130, 9224-9225 (2008); Czaban, J. A. et al., Nano Lett. 9, 148-154 (2009); Tsakalakos, L. et al., Appl. Phys. Lett. 91 (2007); and Kelzenberg, M. D. et al., Nano Letters 8, 710-714 (2008)). Due to their single-crystalline nature, they have the potency for high performance solar modules. While nanowires can be grown non-epitaxially on amorphous substrates, their random orientation on the growth substrates could limit the explored device structures.

Conventional thin-film PVs rely on the optical generation and separation of electron-hole pairs (EHPs) with an internal electric field. Among different factors, the absorption efficiency of the material and the minority carrier life time often determine the energy conversion efficiency. In this regard, simulation studies have previously shown the advantages of 3D cell structures, such as those utilizing coaxially doped vertical nanopillar arrays, in improving the photo-carrier separation and collection by orthogonalizing the direction of light absorption and EHPs separation (e.g., see Kayes, B. M. et al., J. Appl. Phys. 97, 114302 (2005)). This type of structure is particularly advantageous when the thickness of the device is comparable to the optical absorption depth and the bulk minority carrier life times are relatively short. Under such circumstances, the optical generation of carriers is significant in the entire device thickness and the 3D structure facilitates the efficient EHPs separation and collection. Additionally, 3D structures have been shown to enhance the optical absorption efficiency of the material (e.g., see Tsakalakos et al.; and Spurgeon, J. M. et al., Journal of Physical Chemistry C 112, 6186-6193 (2008)). Specifically, photoelectrochemical studies of Cd(Se, Te) nanopillar (NPL) arrays have shown that the NPL array photoelectrodes exhibit enhanced collection of low-energy photons absorbed far below the surface, as compared to planar photoelectrodes (e.g., see Spurgeon et al.). These results demonstrate the potential advantage of non-planar cell structures, especially for material systems where the bulk recombination rate of carriers is larger than the surface recombination rate. However, to date the conversion efficiency of the fabricated PVs based on coaxial NPL arrays have been far from the simulation limits (see Kayes et al.), with the highest reported efficiency of ˜0.5% (see Garnett et al.) arising from un-optimized NPL dimensions, poor NPL density and alignment, and/or low pn junction interface quality (see Czaban et al.; and Tsakalakos et al.), although single nanowire devices have demonstrated better efficiencies (see Kelzenberg et al.). Furthermore, controlled and cost-effective process schemes for the fabrication of large-scale solar modules that utilize highly dense and ordered arrays of single-crystalline NPL arrays have not been demonstrated.

### SUMMARY OF THE INVENTION

In one embodiment of this invention a novel 3D solar cell structure is described in which dense, ordered arrays of nanopillars are disposed atop an amorphous substrate. More particularly, the nanostructure of the present invention includes a conductive substrate, optionally an insulating layer on the conductive substrate, metal nanoparticles, and elongated single crystal nanostructures. The insulating layer includes an array of pore channels. The metal nanoparticles are located at bottoms of the pore channels. The elongated single crystal nanostructures contact the metal nanoparticles and extend out of the pore channels.

An embodiment of a photovoltaic device of the present invention includes a conductive layer, an insulating layer, a photoabsorption layer, elongated single crystal nanostructures, and metal nanoparticles. The elongated single crystal nanostructures are arranged in an array with axes of the elongated nanostructures perpendicular to a surface of the conductive layer. The elongated nanostructures extend from the insulating layer and into the photoabsorption layer. The metal nanoparticles conductively couple the elongated nanostructures to the conductive layer.

In another embodiment of the invention a novel template-assisted VLS process is described for forming the single crystal silicon nanopillars upon a conductive, amorphous substrate. One embodiment of the method includes forming an insulating layer on a conductive substrate. The insulating layer, in an anodization/etch process forms pore channels arranged in an array. Metal nanoparticles are then formed in the pore channels. The metal nanoparticles conductively couple to the conductive layer. In one embodiment the process is conducted at a temperature above which the metal nanoparticles are in the liquid state. Elongated single crystal nanostructures are then formed in the pore channels via VLS growth. A portion of the insulating layer is etched away, which leaves the elongated single crystal nanostructures extending out of the insulating layer. In one embodiment, a polycrystalline thin film of hole-rich CdTe is then grown over the exposed ends of the nanopillars, resulting in the nanopillars being embedded in the polycrystalline film.

In yet another embodiment of the invention, by modifying the processing of the formed insulating layer, pore channels of different cross section can be obtained, which in the VLS process can lead to nanopillars of different cross sectional shape, such as circular, square, rectangular, oval, triangular, and the like, as well as nanopillars of the same cross sectional shape, but of varying cross sectional dimension along their length, enabling optimization of pillar configurations. In still other embodiments a greater portion of the insulating layer can be etched away after pillar formation, to leave a dense array of free standing nanopillar rods. In this embodiment, rather than embedding the ends of the rods in the polycrystalline film, each individual rod can be coated with polycrystalline and/or single-crystalline film to form a radial junction, or overtop to form an extended rod with an axial junction, these variations more fully described hereinafter.

### BRIEF DESCRIPTION OF THE DRAWINGS

The present invention is described with respect to particular exemplary embodiments thereof and reference is accordingly made to the drawings in which:

FIGS. 1A and 1B illustrate an embodiment of a nanostructure of the present invention.

FIG. 2 illustrates an embodiment of a photovoltaic device of the present invention.

FIG. 3: CdS/CdTe SNOP (solar nanopillar) cells of the present invention. FIG. 3a, Energy band diagram of a CdTe/CdS PV. FIG. 3b, Cross-sectional schematic of an SNOP cell, illustrating the enhanced carrier collection efficiency. FIG. 3c, SNOP cell fabrication process flow.

FIG. 4: Electron microscopy images of an example SNOP cell of the present invention at different stages of fabrication. FIG. 4a, Scanning electron microscopy (SEM) image of as-made AAM (anodic alumina membrane) with highly ordered pores. FIG. 4b, SEM image of CdS NPL (nanopillar) array after partial etching of the AAM. FIG. 4c, Transmission electron microscopy (TEM) image of the interface between a single-crystalline CdS NPL and poly-crystalline CdTe thin film.

FIG. 5: Performance characterization of an example SNOP cell of the present invention. FIG. 5a, An optical image of a fully fabricated SNOP cell bonded on a glass substrate. FIG. 5b, I-V characteristics at different illumination intensities. FIG. 5c, Short circuit current density, J_{sc} which shows a near linear dependence on the illumination intensity, while the fill factor, FF slightly decreases with increase of intensity. FIG. 5d, Open circuit voltage, V_{oc} slightly increases with intensity and the solar energy conversion efficiency is nearly independent of the illumination intensity for P=17˜100 mW/cm².

FIG. 6: Effects of the NPL geometric configuration on the device performance. FIG. 6a, Experimentally obtained efficiency of SNOP cells as a function of the embedded NPL height, H. The CdTe film thickness is maintained constant at ˜1 μm. FIG. 6b, Theoretical simulation of the SNOP cell efficiency as a function of H, in qualitative agreement with the observed experimental trend shown in FIG. 6a. FIGS. 6c and 6d, Visualization of the Shcokley-Read-Hall (SRH) recombination in SNOP-cells with H=0 nm and H=900 nm, respectively. Space charge and carrier collection region is quite small when H=0 nm, resulting in a major carrier loss in the upper portion of the CdTe film through recombination, where there is a high electron-hole pair (EHP) optical generation rate. However, the space charge and carrier collection region is significantly enlarged when H=900 nm, thus the total volumetric carrier recombination loss is greatly reduced.

FIG. 7: Mechanically flexible SNOP cells. FIG. 7a, Schematic of an embodiment and FIG. 7b, an optical image of an example of a bendable SNOP module embedded in PDMS of the present invention. FIG. 7c, and FIG. 7d, Theoretical simulation of the strain for a flexible SNOP cell (PDMS thickness˜4 mm), showing only ˜0.01% maximum strain in the NPLs. FIG. 7e, I-V characteristics of a flexible cell for various bending radius. FIG. 7f, Performance characterization of a flexible SNOP cell, showing minimal change in V_{oc} and η upon bending of the substrate. The inset is a picture of the set up for bending the flexible modules.

FIG. 8: The first, FIG. 8a, and second, FIG. 8b, imprint on an Al substrate with a straight line optical diffraction grating. FIGS. 8c and 8d are SEM images of an example of the AAM after first and second anodization steps, respectively.

FIG. 9: Nanopillar exposure length as a function of the AAM etching time in 1 M NaOH solution at room temperature.

FIG. 10: FIG. 10a is an SEM image of an example CdTe film after ion milling. FIG. 10b provides X-ray diffraction patterns for an example CdTe film that confirm that example as-grown CdTe films are polycrystalline with mixed phase of hexagonal close packed and cubic structures.

FIG. 11 provides an optical transmission spectrum of example Cu/Au top contacts.

FIG. 12: FIG. 12a is a low magnification TEM image of an example CdS NPL and the selected area electron diffraction pattern (inset), showing its single crystalline nature. FIG. 12b is a high resolution TEM image that resolves lattice fringes, indicating [110] growth direction. FIG. 12c is an energy dispersive x-ray spectroscopy (EDS) taken from center part of an example NPL. FIG. 12d provides room-temperature photoluminescence measured from an example single CdS NPL.

FIG. 13: FIG. 13a is an SEM image of an example ordered CdS NPL array after partial etching of AAM. The inset is a photograph of four substrates with exposed CdS NPL heights of 0, 60, 163 and 231 nm (left to right, respectively). FIG. 13b provides reflectance spectra of the four substrates shown in the inset of FIG. 13a. Compared with blank AAM on Al substrate, the reflectance is greatly reduced, with 231 nm exposed NPL height, resulting in a reflectance minima of ˜1.6%.

FIG. 14: Dark, FIG. 14a, and light, FIG. 14b, I-V curves of the solar cell obtained at 5 different temperatures from 297K to 333K. FIG. 14c shows that open circuit voltage (V_{oc}) decreases with temperature.

FIG. 15: Simulation of SNOP-cell efficiency versus the radius of CdS NPL. The material parameters are adopted from Table 1 and the device structure is shown in FIG. 6d.

FIG. 16: Structures of an embodiment of an SNOP-cell, FIG. 16a, and a conventional planar cell, FIG. 16b, used for Sentaurus simulation. FIG. 16c provides conversion efficiencies of the SNOP and planar cells versus the minority carrier (electron) diffusion length of the CdTe film. The total device thickness is fixed at 1.3 μm including electrodes. The inset shows their ratio, depicting the advantage of SNOP-cell, especially when the minority carrier life times are relatively low.

FIG. 17: Simplified schematic for a roll-to-roll fabrication process of large scale for producing SNOP cell panels.

FIG. 18: Graphical cost breakdown fo SunPower and the technology of the present invention, which is labeled as “LBNL.”

FIG. 19: Process schematic for the template assisted VLS synthesis of (1) square and (b) rectangular NPL arrays.

FIG. 20: Composite presentation including a three dimensional illustration of a dual diameter NPL (DNPL) according to one embodiment of the invention, a simulation plot, and a number of SEM images of the obtained dual diameter NPL structure.

### DETAILED DESCRIPTION OF THE INVENTION

Embodiments of the present invention include a nanostructure, a photovoltaic device, and methods of fabricating the nanostructure and the photovoltaic device.

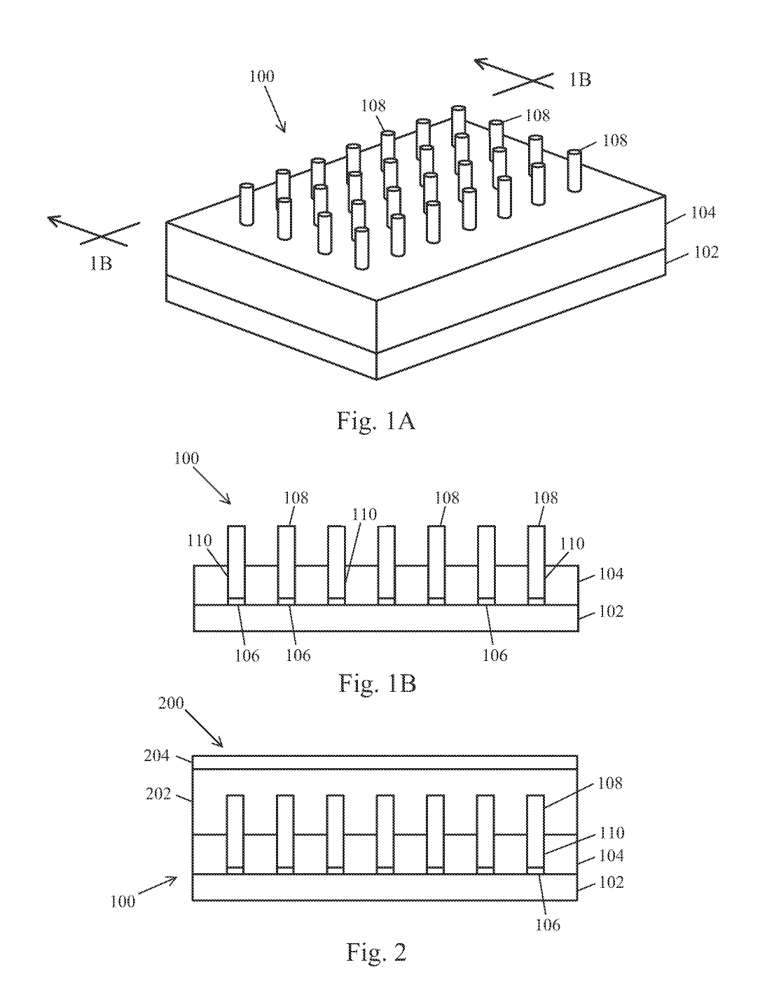

An embodiment of a nanostructure of the present invention is illustrated in FIGS. 1A and 1B. The nanostructure 100 includes a conductive layer 102 (e.g., a conductive substrate), an insulating layer 104, metal nanoparticles 106, and an array of elongated single crystal nanostructures 108. The insulating layer includes an array of pore channels 110. The metal nanoparticles 106 reside at bottoms of the pore channels 110 and are conductively coupled to the conductive layer 102. A thin barrier layer (not shown) may physically separate the metal nanoparticles 106 from the conductive layer 102. The thin barrier layer may comprise a material that forms the insulating layer but which is sufficiently thin that the metal nanoparticles 106 conductively couple to the conductive layer 102. In an embodiment, the conductive layer 102 is made of aluminum or an aluminum alloy (e.g., aluminum foil). In an embodiment, the insulating layer is made of aluminum oxide (i.e. alumina). In an embodiment, the metal nanoparticles are made of a transition metal (e.g., Au). In an embodiment, the elongated single crystal nanostructures are made of a semiconductor. For example, the elongated single crystal nanostructures may be Si or a compound semiconductor (e.g., CdS). In an embodiment, the elongated single crystal nanostructures are nanopillars. In an embodiment, the elongated single crystal nanostructures are arranged in a regular array (i.e. an array having repeating separation distances between neighboring elongated nanostructures). It is anticipated that the separation distances of the regular array may be tuned to provide a more optimal device that makes use of the nanostructure 100.

As used herein, the prefix “nano” means that the item or items that follow the prefix include a dimension on the nanometer scale. As used herein, the term “elongated nanostructure” means an elongated structure having a width or cross-sectional dimension on the nanometer scale. The term “elongated nanostructure” includes nanowires, nanorods, nanopillars, and other similar nanostructures. As used herein, the term “nanoparticle” means a structure having a dimension on the nanometer scale that in some embodiments may be elongated.

An embodiment of a photovoltaic device of the present invention is illustrated in FIG. 2. The photovoltaic device 200 includes the nanostructure 100 and a photoabsorption layer 202. In an embodiment, the elongated single crystal nanostructures 108 are made of n-type CdS and the photoabsorption layer 202 is made of p-type CdTe. In an embodiment, the photovoltaic device 200 further includes an at least semi-transparent conductive layer 204. For example, the at least semi-transparent conductive layer 204 may be made of layers of Cu and Au or it may be made of ITO (indium tin oxide). In operation, the photovoltaic device 200 is exposed to light (e.g., sunlight), which illuminates the photoabsorption layer 202 through the at least semi-transparent conductive layer 204. This generates carriers (i.e. holes and electrons) in the photoabsorption layer 202. One type of carrier flows to the elongated single crystal nanostructures 108 and the other type of carrier flows to the at least semi-transparent conductive layer 204. In an embodiment, the conductive layer 102 of the photovoltaic device 200 l may be attached to a flexible material (not shown) and at least semi-transparent flexible material (not shown) may cover the at least semi-transparent conductive layer 204.

It will be readily apparent to one skilled in the art that other semiconductors may be used in lieu of the n-type CdS and p-type CdTe. For example, the elongated single crystal nanostructures 108 may be made of Si, Ge or a III-V semiconductor such as GaAs or a II-VI semiconductor other than CdS and the photoabsorption layer 202 may be made of poly crystalline Si or a III-V semiconductor such as GaAs or a II-VI semiconductor other than CdTe.

An embodiment of a method of fabricating the nanostructure 100 begins with forming an insulating layer on a conductive layer. The insulating layer includes an array of pore channels. In an embodiment, forming the insulating layer includes forming an anodic alumina membrane (AAM) having the pore channels on aluminum foil. In an embodiment, the method includes performing a barrier etch of bottoms and sides of the pore channels, which leaves at most a thin layer of alumina at the bottoms of the pore channels and which expands the pore channels. The method continues with forming metal nanoparticles in bottoms of the pore channels. For example, forming the metal nanoparticles may employ an electrochemical deposition technique using an alternating current. The elongated single crystal nanostructures (e.g., nanopillars) are then formed in the pore channels. In an embodiment, the elongated single crystal nanostructures are formed using a vapor-liquid-solid (VLS) process performed in a thermal furnace. In the vapor-liquid-solid process, the metal nanoparticles (e.g., the Au nanoparticles), in liquid phase, act as catalysts to initiate growth of the elongated single crystal nanostructures. During the vapor-liquid-solid process, a size of each of the metal nanoparticles may be reduced but at least a portion of each deposited nanoparticle remains at a bottom of its respective pore channel. A selective etch is then performed which among other things etches away a portion of the insulating layer. This leaves the elongated single crystal nanostructures extending out of the insulating layer.

By this VLS method, we have been able to directly grow highly regular, single-crystalline nanopillar (NPL) arrays of optically active semiconductors on aluminum substrates which are then configured as solar cell modules. As an example, we demonstrate a PV (photovoltaic) structure that incorporates 3D, single crystalline n-CdS NPLs, embedded in poly-crystalline thin films ofp-CdTe, to enable high absorption of light and efficient collection of the carriers. Through experiments and modeling, we demonstrate the potency of this approach for enabling highly versatile solar modules on both rigid and flexible substrates with enhanced carrier collection efficiency arising from the geometric configuration of the NPLs.

The use of template-assisted, VLS growth of highly ordered, single-crystalline NPLs on aluminum substrates is a highly versatile approach for fabricating novel solar cell modules. This approach can simplify the fabrication process of PVs based on crystalline compound semiconductors while also enabling the exploration of new device structures.

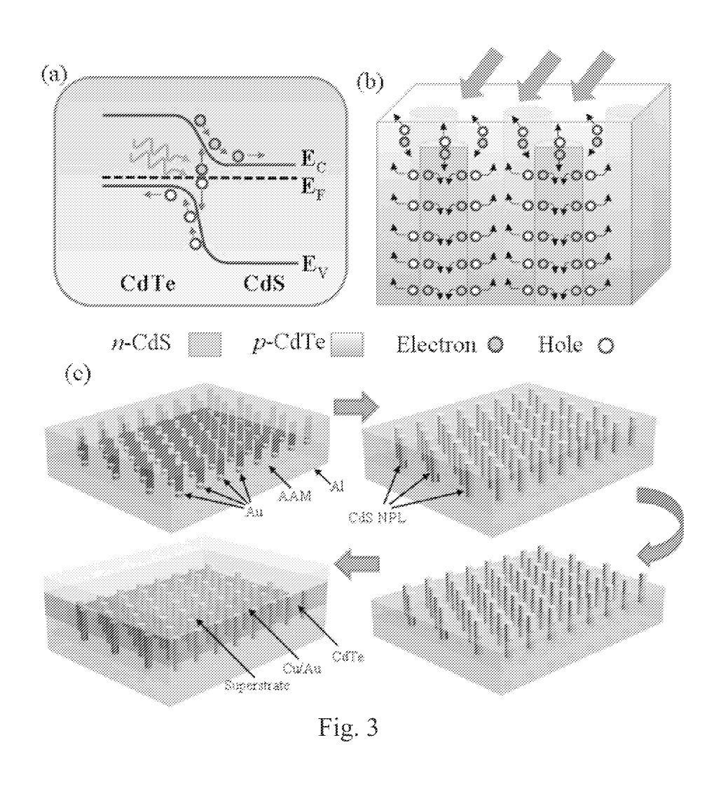

In order to explore the potency of this strategy, we synthesized highly ordered, single crystalline NPLs of n-CdS directly on an aluminum substrate and embedded them in a thin film ofp-CdTe as the optical absorption material (FIG. 3). PVs rely on the optical generation and separation of electron-hole pairs (EHPs) with an internal electric field, as shown in FIG. 3a. Here, a 3D cell structure is employed in which a vertical NPL array is embedded in a photoabsorption material as shown in FIG. 3b.

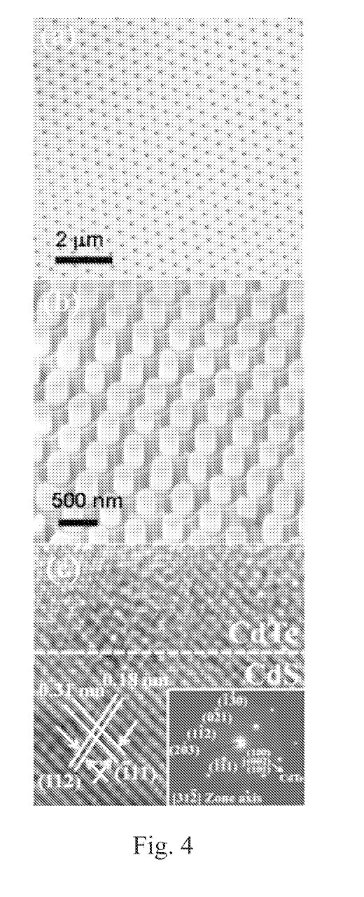

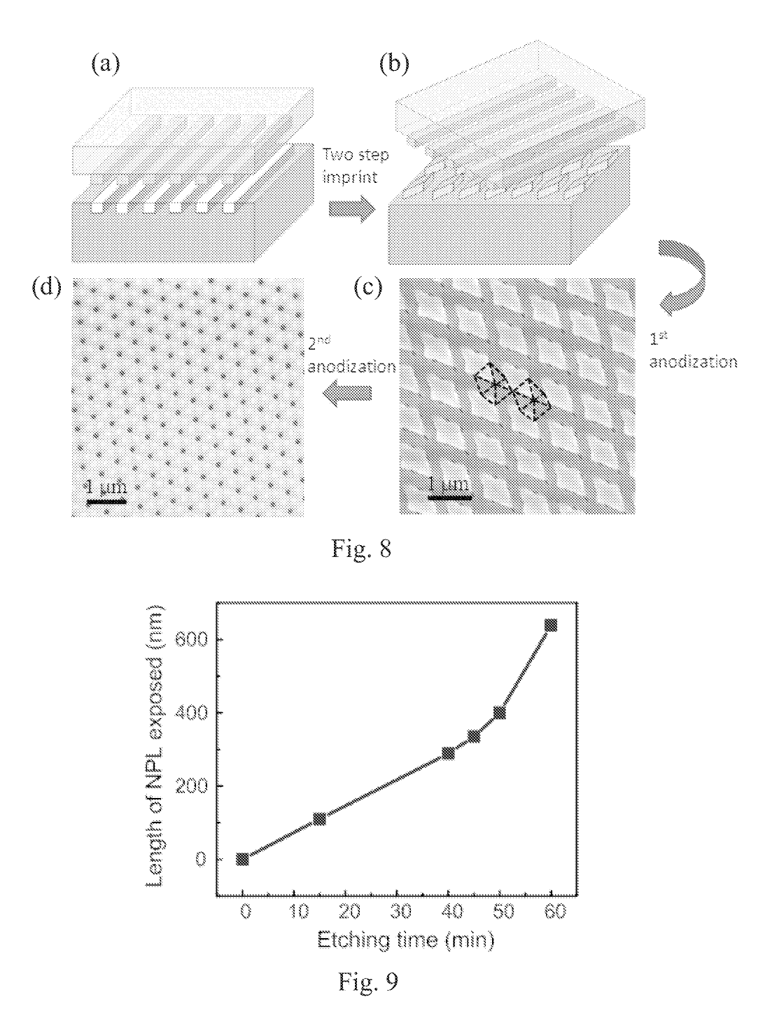

The fabrication process described herein for 3D solar nanopillar-cells (SNOP-cells) utilizes highly periodic anodic alumina membranes (AAMs) as the template for the direct synthesis of single-crystalline nanostructures. This approach has been widely used for fabrication of dense arrays of metallic, semiconductor and organic one-dimensional nanostructures, due to the ease of membrane fabrication and nanostructure geometric control (see Fan, Z. Y. et al., Appl. Phys. Lett. 89, 213110 (2006)). Highly regular anodic alumina membranes (AAMs) with thickness ˜2 μm and pore diameter ˜200 nm were first formed on aluminum foil substrates (FIG. 3c) by adopting previously reported processes (Supplementary information and FIG. 8) (see Masuda, H. et al., Appl. Phys. Lett. 71, 2770-2772 (1997); and Mikulskas, I. et al., Adv Mater 13, 1574-1577 (2001)). FIG. 4a shows a scanning electron microscopy (SEM) image of an AAM with long range and near-perfect ordering after anodization. A barrier thinning process was applied to branch out the pore channels and reduce the alumina barrier layer thickness at the bottom of the pores to a few nanometers (see Fan et al.). A ˜300 nm thick Au layer was then electrochemically deposited at the bottom of the pore channels with an alternating current method (Methods section).

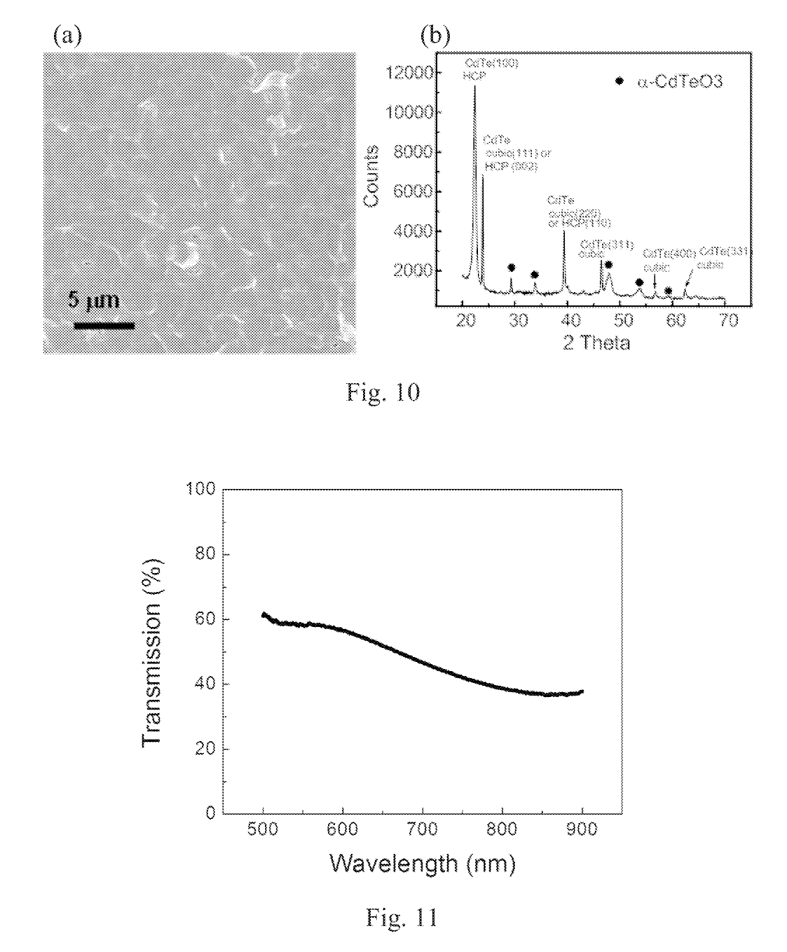

The AAM with the electrodeposited Au catalytic layer was then placed in a thermal furnace to carry out the synthesis of the CdS NPL array by the vapor-solid-liquid process (Methods section). In order to form the 3D NPL structures, the AAM was partially and controllably etched in 1N NaOH at room temperature. Notably, this etch solution is highly selective and does not chemically react with the CdS NPLs. FIG. 4b shows a 3D NPL array with exposed depth, H˜500 nm. The exposed depth was varied by tuning the etching time (Supplementary information and FIG. 9) to enable a systematic study of the effect of the geometric configuration on the conversion efficiency. A p-type CdTe thin film with ˜1 μm thickness (Supplementary information and FIG. 10) was then deposited by chemical vapor deposition (Methods section) to serve as the photoabsorption layer owing to its near-ideal band-gap (E_{g}=1.5 eV) for solar energy absorption.

Finally, the top electrical contact was fabricated by the thermal evaporation of Cu/Au (1 nm/13 nm) which enables low barrier contacts to the p-CdTe layer due to the high work function of Au. It is worth noting that although the Cu/Au bilayer was deposited thin, its optical transmission spectrum (FIG. 11) shows that it has only ˜50% of transparency which results in a major cell performance loss since light is shined from the top during the measurements. Further top-contact optimization is contemplated, for instance, by exploring the use of transparent conductive oxide contacts. The back electrical contact to the n-type CdS NPLs was simply the aluminum support substrate which greatly reduces the complexity of the fabrication. The entire device was then bonded from the top to a transparent glass support substrate with epoxy in order to encapsulate the structures.

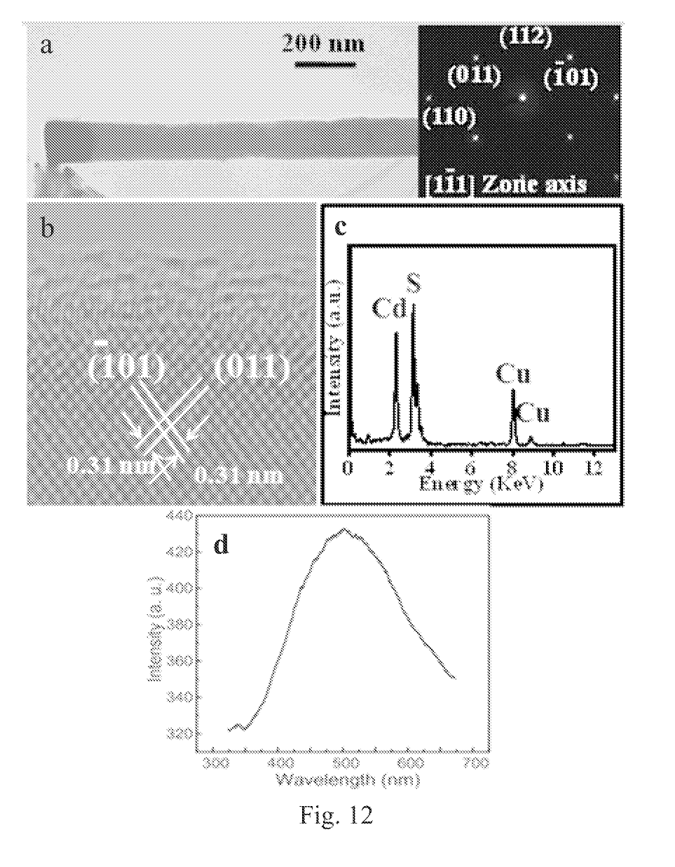

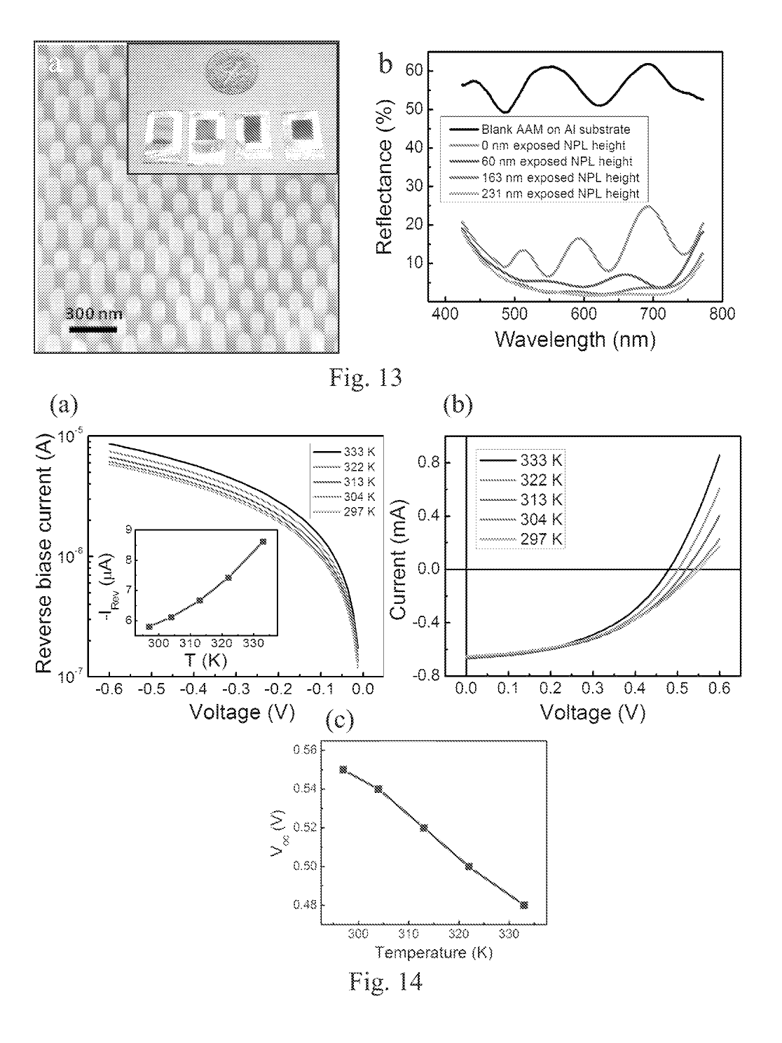

One of the primary merits of our fabrication strategy rests in the ability to produce high density, single-crystalline NPL arrays on an amorphous substrate with fine geometric control, without relying on epitaxial growth from single crystalline substrates. The single-crystalline nature of the grown CdS NPLs is confirmed by transmission electron microscopy (TEM) analysis with a near 1:1 stoichiometric composition observed by EDS (Supplementary information and FIG. 12). Notably, abrupt atomic interfaces with the poly-crystalline CdTe layer are observed (FIG. 4c). We have observed reduced reflectivity from CdS NPL arrays especially when inter-pillar distance is small (FIG. 13). This observation suggests that 3D NPL based cell modules can potentially improve the light absorption while enhancing the carrier collection.

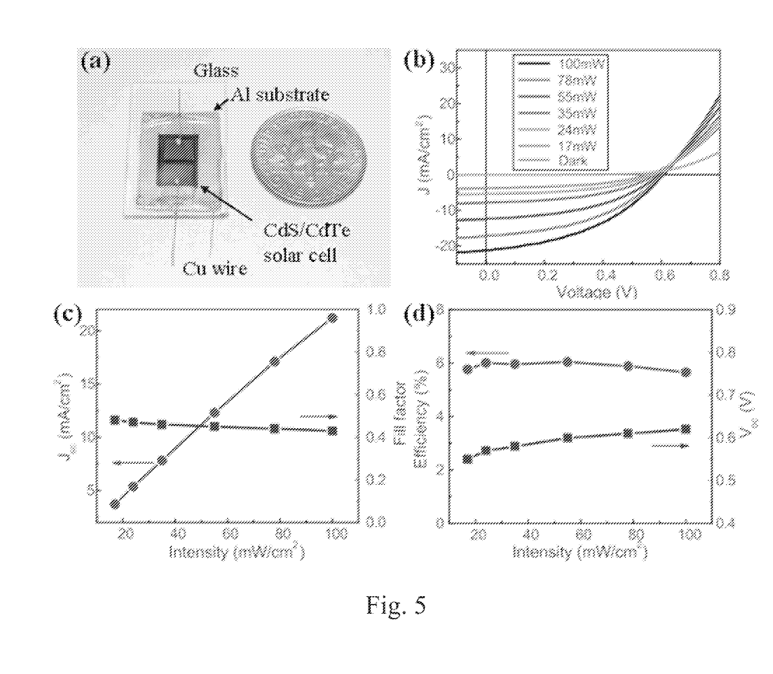

An optical image of a fully fabricated SNOP-cell is shown in FIG. 5a with an active surface area of 5×8 mm. The performance was characterized by using a solar simulator (LS1000, Solar Light Co.) without a heat sink. FIG. 5b demonstrates the I-V characteristics of a typical cell under different illumination intensities, P, ranging from 17 mW/cm² to 100 mW/cm² (AM 1.5G). Specifically, an efficiency (η) of ˜6% is obtained with open circuit voltage V_{oc}˜0.62V, short circuit current density J_{sc}˜21 mA/cm² and fill factor FF˜0.43 under AM1.5G illumination. The I-V curves cross over each other above V_{oc}, which can be attributed to the photoconductivity of CdS. The dependency of the performance characteristics on the illumination intensity is depicted in FIGS. 5c and 5d. As expected, J_{sc} exhibits a near linear dependency on the intensity since in this regime the photocurrent is proportional to the photon flux with a constant minority carrier life time. On the other hand, V_{oc} only increases slightly from 0.55 V to 0.62 V with linear increase of J_{sc}, which we attribute to a slight thermal heating of the device (Supplementary information and FIG. 14) since a cooling chuck was not used during the measurements. Since the efficiency of a solar cell is expressed as η=V_{oc}×J_{sc}×FF/P and FF slightly decreases with light intensity, the extracted η˜6% shows minimal dependence on the illumination intensity as depicted in FIG. 5d. It should be noted that this efficiency is obtained without the use of antireflective surface coating or concentrators.

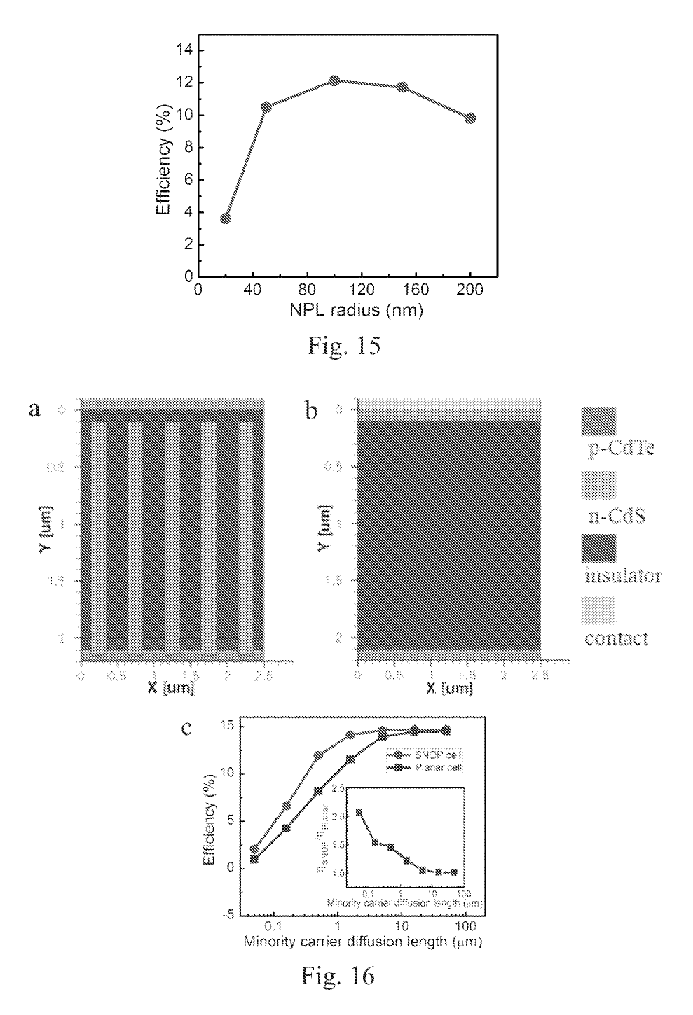

While the conversion efficiency of our first generation SNOP cells reported here is already higher than most of the previously reported PVs based on nanostructured materials (see Garnett et al., Czaban et al., and Tsakalakos et al.) further optimizations will be needed to meet high performance application requirements. Notably, the reported efficiency is higher than that of the planar CdS/CdTe cell with comparable CdTe film thickness (e.g., see Marsillac, S. et al., Solar Energy Mater. Solar Cells 91, 1398-1402 (2007)), but lower than those with optimal CdTe film thicknesses. As confirmed by simulation (FIGS. 15 and 16), we speculate that the efficiency can be readily enhanced in the future through further device and materials optimization. One such approach has been to develop and test dual diameter NPLs having top contacts with higher optical transparency and lower parasitic resistances, as discussed below.

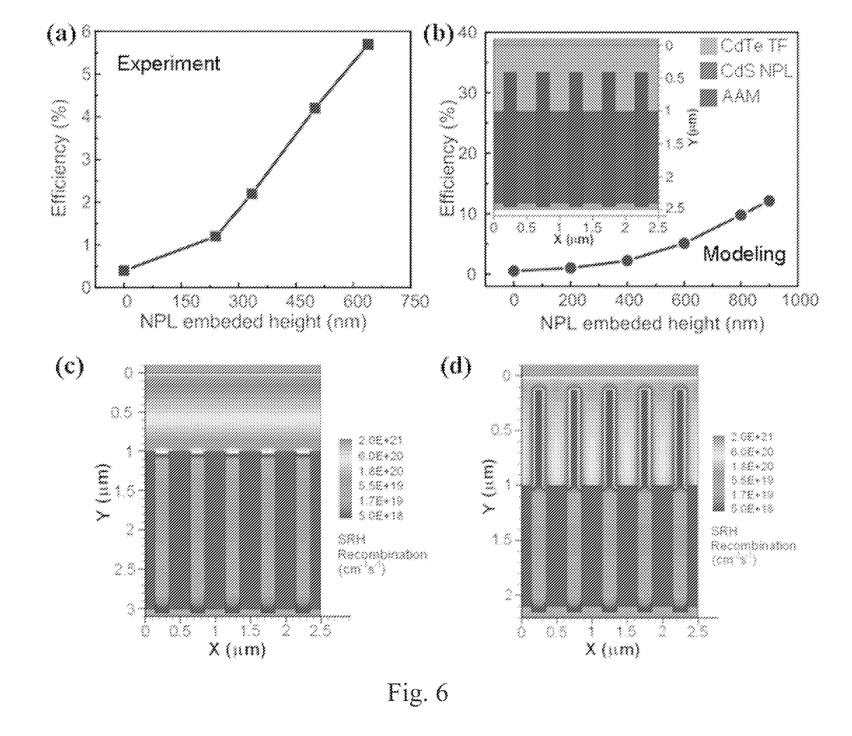

To further examine the effect of the geometric configuration of the NPLs on the overall conversion efficiency, devices with different embedded CdS NPL length, H, (controlled by the etching time of the AAM, FIG. 9) were fabricated and carefully characterized while maintaining the same overall CdTe thickness. As evident from FIG. 6a, conversion efficiency drastically and monotonically increases with H. Specifically, η=0.4% is obtained for H=0 nm. In such a case, only the top surface of the CdS NPLs is in contact with the CdTe film. As a result, only a small space charge region is obtained with low carrier collection efficiency. The majority of the photo-generated carriers are lost by recombination in the CdTe film, especially through nonradiative recombination at the defects-rich grain boundaries. By increasing H, the space charge region area is effectively increased with much improved carrier collection efficiency. In particular, the device conversion efficiency is increased by more than one order of magnitude when H is increased from 0 to ˜640 nm. This is attributed to the reduced distance needed for the photogenerated electrons to diffuse before they are collected by the NPLs, as schematically shown in FIG. 3b.

To interpret the observed trend of the efficiency dependency on the geometric configuration, 2D theoretical simulations were performed by using Sentaurus simulator (FIGS. 6b-6d). The details of the simulation can be found in the supplementary information. The simulated efficiency as a function of H, shown in FIG. 6b, is in qualitative agreement with the experimentally observed trend. Meanwhile, the recombination rate for H=0 and 900 nm is visualized and plotted in FIGS. 6c and 6d, respectively. It is clearly evident that the space charge and carrier collection region is drastically enhanced for H=900 nm, which reduces the total volumetric recombination of photo-generated carriers. Additionally, further simulation confirms that the 3D configuration of SNOP-cells enhances the performance as compared to conventional planar CdS/CdTe solar cells, especially for devices with short minority carrier diffusion lengths (FIG. 16). It should be noted that in these simulations, enhanced optical absorption (i.e., reduced reflectance) due to the 3D geometric configuration of the NPLs is ignored which may further enhance the expected performance of the SNOP-cell as compared to planar structures. However, the SNOP structure may be disadvantageous when interface recombination is the limiting factor for cell performance (for instance, when the bulk minority carrier lift times are long) due to its higher interface area as compared to conventional planar-structured PVs. Further exploration of minority carrier life times in these structures is needed in the future.

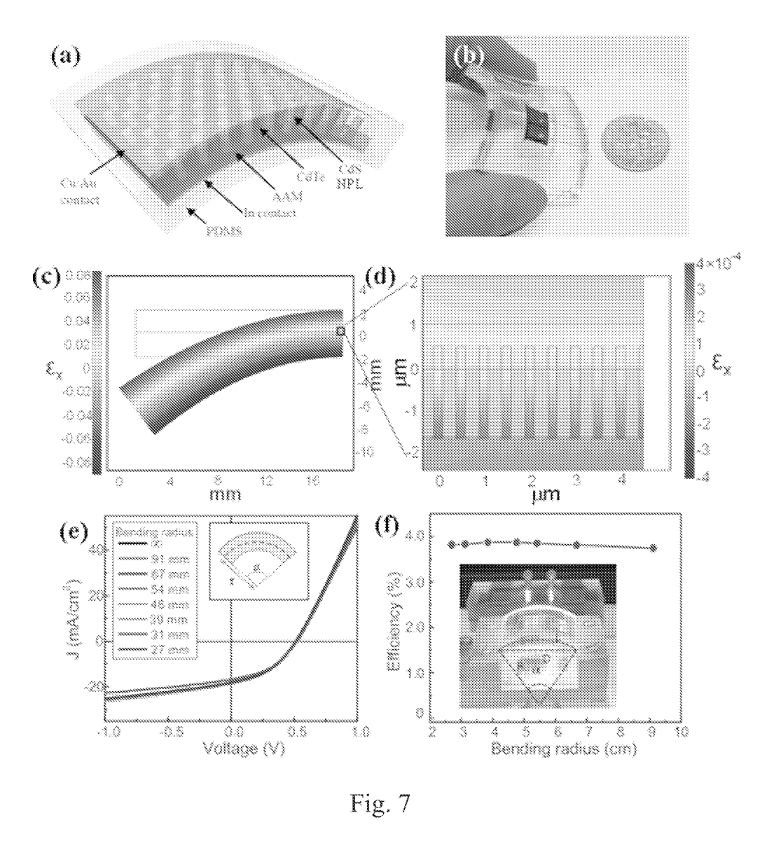

Mechanically flexible solar cells are of particular interest for a number of practical applications. In this regard, we fabricated bendable SNOP-cells embedded in PDMS (FIG. 7a). Simply, a layer of PDMS (˜2 mm thick) is cured on the top surface following the top-contact metallization process. The aluminum back substrate is then removed by a wet chemical etch, and a ˜200 nm thick indium layer is deposited as the bottom contact to the n-CdS NPLs. Finally, another layer of PDMS (˜2 mm thick) is cured on the back side to finish the encapsulation process. FIG. 7b shows an optical image of a fully fabricated, mechanically flexible cell. In such a device configuration, the NPLs are placed in the neutral mechanical plane of the PDMS substrate which minimizes the strain on the active elements. To examine the effect of strain, finite element simulation (Comsol Multiphysics 3.3) was performed (FIGS. 7c and 7d). From the simulation, when the substrate is mechanically bent with a curvature radius of 3 cm, the 4 mm thick PDMS substrate shows a maximum tensile and compressive strain of ˜8% at the top and bottom surfaces, respectively. However, since the active devices are only a few micron thick (NPL length˜2 μm) and are placed close to the center of the PDMS substrate, the maximum observed strain in the NPLs is only ˜0.01%, which suggests that the flexible photovoltaic devices can sustain large bending without structural degradation. The I-V characteristics and conversion efficiencies of a SNOP module under different bending conditions are shown in FIGS. 7e and 7f. It is clear that the bending of the devices only affects the cell performance marginally, and repetitive bending does not degrade the cell performance.

In summary, we have demonstrated a highly versatile approach for the controlled fabrication of ordered, single-crystalline semiconductors on aluminum substrates which are then configured as solar cell modules. While this fabrication approach enables the exploration of a wide range of device structures and materials systems, here, we specifically examined n-type CdS NPLs embedded in p-type CdTe thin films as the active component of PVs with unique carrier collection characteristics arising from the 3D geometric configuration of the NPLs. Additionally, the cells can be readily embedded in mechanically flexible substrates, and can be bent to small radii without any degradation to the device performance.

While we have demonstrated the potency and the capabilities of the SNOP-cell module, further work may optimize performance and lower process development cost. Specifically, while the 3D configuration of the proposed single-crystalline cells may potentially enable more efficient light absorption and carrier collection, further optimization of the contacts, in terms of both optical and electrical transparency, is expected to enable performances that are predicted by the simulation. The ability to directly grow single crystalline structures on large aluminum sheets, as demonstrated in this work, is highly attractive for potentially lowering the materials processing costs. Additionally, the 3D configuration of the crystalline NPLs can relax the materials requirements in terms of quality and purity which can further lower the costs. Such materials cost reductions, however, are partially offset by the device fabrication steps, including the anodization steps and the top contact formation. In the case of latter, exploration of various low-cost, conductive film deposition processes, such as ink jet printing may be a necessity in the future to further enhance the versatility of the proposed solar modules.

### Additional Nanopillar Geometric Structures

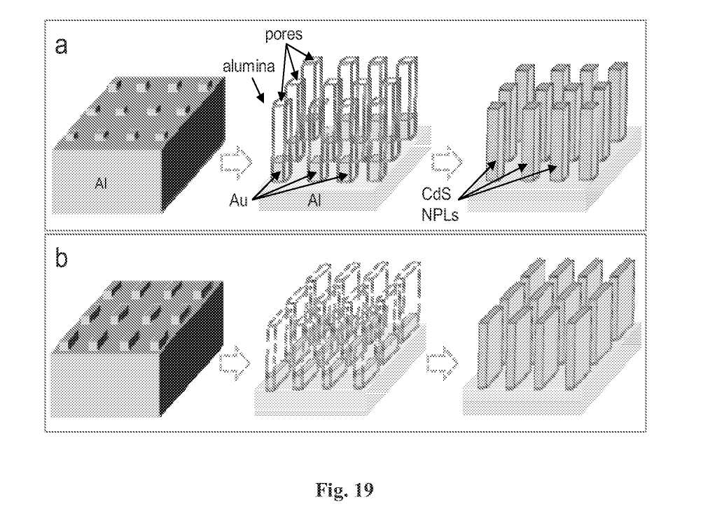

The template assisted VLS processes of this invention may also be use to form nanopillars of various cross sectional shape and geometry, which shape can affect the physical characteristics of the nanopillar. Using techniques developed for anodized alumina membranes (AAMs) we can change the cross section of the created pores. We have been able to utilize the template assisted VLS growth process for the fabrication of highly regular and single crystalline NPL arrays with tunable shapes such as square or rectangular, among other possible shapes, as illustrated in FIG. 19, in addition to circular, as defined by the shape of the template. The process can be applied for example to the synthesis of CdS and Ge nanopillars, presenting a generic platform toward the controlled synthesis of nanostructures with tunable shape and geometry.

The formation of ordered porous alumina membranes by anodization is a well known and understood technique. In order to form pillars of square or rectangular cross section we pretextured an electrochemically polished aluminum substrate using a straight line silicon diffraction grating as the mold. A two step imprinting process was utilized to define the Aluminum surface morphology followed by the anodization step. By varying the angle between imprint orientation and pitch of the gratings, different indentation shapes can be formed on the aluminum surface, resulting in pores with different cross sectional shapes following the subsequent anodization step. This control is enabled since the indentation regions formed by the overlap of the two imprinting steps act as nucleation sites for the pore development due to local increases in the rate of field enhanced dissolution of the oxide. Pore depth can be manipulated by control of the anodization time. A current ramping technique is then used to thin the alumina barrier at the bottom of the pores in preparation for a subsequent metal catalyst (e.g. gold) electro deposition step. The electrodeposited metal is then used as the catalytic seed for the template assisted VLS growth of NPLs.

To achieve the faithful reproduction of the shape of the pores during single crystal growth, sufficient metal must be deposited into the pores to ensure a complete filling of the cross sectional pore area. If there is insufficient metal in the pores, spherical metal particles may be formed, thereby resulting in the growth of cylindrical NPLs with diameters smaller than the width of the pores. It is to be appreciated that other shapes such as triangular, oval and the like are contemplated by the methods of this invention. We have also found the process to be highly generic for various material systems. By way of example CdS and Ge nanopillar arrays with square, rectangular and circular cross sections have been fabricated.

In another approach dual diameter nanopillars (DNPL) can be formed and used as a means for maximizing optical absorption. By using template-assisted bottom up growth such a dual diameter NPL array can be conveniently constructed. Since the diameter of the NPL is controlled by the pore size of the AAM template, the dual diameter structure can be realized by using a multistep anodization process at the same voltage, but with a different pore widening etching time for each step.

This novel dual diameter NPL structure was fabricated with a small diameter tip for minimal reflectance and a large diameter base for maximal absorption of the penetrating photons, enabling absorption efficiencies of approximately 99% of the incident light over wavelengths of 300-900 nm with a thickness (DNPL length) of only 2 μm.

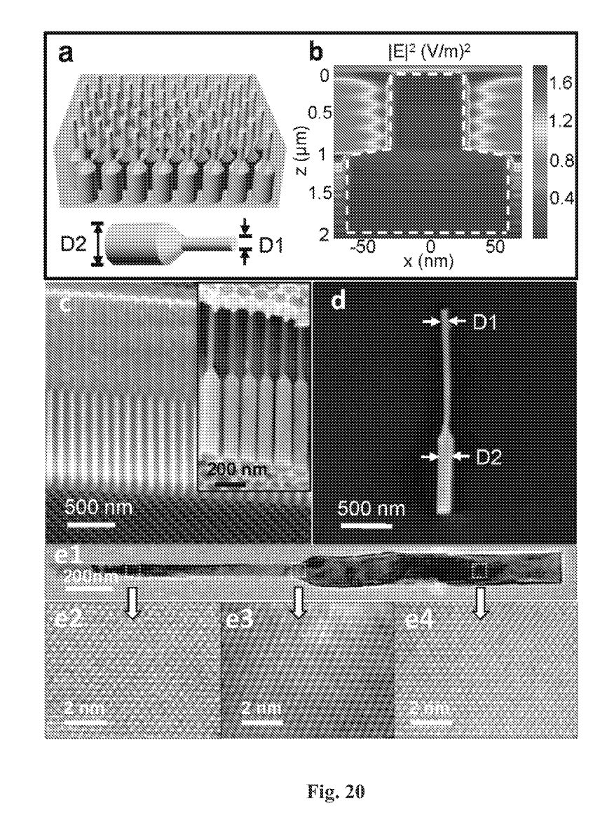

We have also demonstrated this approach for germanium (Ge) nanopillars. Illustrated at FIG. 20a is a schematic of a Ge DNPL array embedded in a sheet of AAM. In FIG. 20b, illustrated is a simulated cross-sectional electric field intensity distribution for a 800 nm wavelength EM wave propagating in a DNPL with a tip diameter D1=60 nm and a base diameter D2=130 nm. FIG. 20c includes cross sectional SEM images of a blank AAM with dual diameter pores and the Ge DNPL (inset) after growth. FIG. 20d is a SEM of a single Ge DNPL after harvesting and drop casting on a silicon substrate. Lastly, FIG. 20e1-e4 are TEM images of a Ge DNPL, showing the single crystalline structure along its axis.

Still other configurations are contemplated by the methods of this invention. For example, NPL radial junctions can be formed where the alumina layer is etched away to reveal the pillars, the pillars then coated on all surfaces with a layer of photoabsorption material to complete the P-N junction. In one embodiment the pillar may be formed of silicon or CdS, and the coating composed of CdTe. Other material combinations are contemplated. In yet another variation, pillars having axial junctions can be formed, where a lower section of the pillar is formed, for example, of CdS, and the upper section formed, for example, of CdTe.

In summary, numerous variations are possible by applying the concepts of the invention and optimization is possible by varying the geometries of the nanopillars.

### Methods

### AAM Fabrication:

Aluminum (Al) foil with a thickness of 0.25 mm (99.99% Alfa Aesar) was cut into 1.2 cm by 2.2 cm pieces and cleaned in acetone and isopropyl alcohol. The substrates were electrochemically polished in a 1:3 (v:v) mixture of perchloric acid and ethanol for 5 min at 5° C. As shown in FIGS. 8a and 8b, the cleaned Al substrates were imprinted twice with a straight line diffraction grating (1200 lines/mm, LightSmyth Technologies) with a pressure of ˜2.2˜10⁴N/cm² and 60 degree rotation between the two imprints. The substrates were anodized in diluted H₃PO₄ solution (1:600 v/v in water) under 195 V DC bias for 1 hour at 1° C. FIG. 8c demonstrates the SEM image of the substrate after the first anodization step. The first layer of AAMs were etched away in a mixture of phosphoric acid (6 wt %) and chromic acid (1.5 wt %) at 63° C. in 1 hour. After etching, the second anodization step was performed under the same condition for 64 min to obtain ˜2 μm thick AAM, with pore pitch ˜490 nm and long range perfect hexagonal ordering, as shown in FIG. 8d.

To carry out the subsequent Au electrodeposition, the barrier layer of the AAMs was thinned with a current ramping technique. Specifically, the AAMs were first etched in 5 wt % H₃PO₄ at 53° C. for 4 min to widen the pores to ˜200 nm. Then the substrates were anodized in 0.2 M H₃PO₄ at 1° C. with a starting voltage of ˜160V and current ˜1 mA per substrate. Electrical current was then decreased by half every 45 min till the voltage reached 36 V. Then H₃PO₄ was replaced by 0.3 M oxalic acid and the fourth anodization step was carried out with a starting voltage ˜38V and current ˜1 mA per substrate. Then the electrical current was decreased by half every 10 min till the voltage reached 4.4 V.

After barrier thinning, the AAMs were briefly etched in 5 wt % H₃PO₄ at 53° C. for 1 min to further thin down the barrier layer. Then Au was electrochemically deposited into the pores with alternating current method by using a Au electrodeposition solution (Technic gold 25 ES) and a potentiostate (SG 300, Gamry Instruments). During the deposition, 60 Hz sinusoidal voltage was applied for 10 min, and the amplitude was adjusted from 3.7 V to 6 V to maintain a peak current density ˜10 mA/cm² at the negative deposition cycle.

### CdS NPL and CdTe Thin Film Growths

The NPL and thin film growths were performed in a 1-inch quartz tube furnace with two resistive heating zones. For the template-assisted, VLS growth of CdS NPLs, CdS powder (˜1g, 99.999%, Alfa Aesar) was used as the source and placed in the first heating zone. The AAM substrate (i.e., the growth template) with the electroplated Au seeds was placed in the second heating zone. H₂ (50 sccm) was used as the transport gas with a chamber pressure of 15 ton. The source and sample heating zones were then heated to 700 and 550° C., respectively. After 30 min of growth, the furnace was turned off and cooled down naturally. The surface of the AAM with grown CdS NPLs was cleaned by ion milling (1 kV Ar+ and ˜80 degree incident angle) for ˜45 min. The ion mill polished sample was then etched in 1M NaOH at room temperature for 50˜60 min to result in an exposed NPL length, H=400-600 nm.

CdTe thin film was deposited on the CdS NPL array in the same furnace. Before the deposition, CdS NPLs were subjected to a 5 sec HF (0.5 wt % in D.I. water) dip to remove the native oxide on the surface. CdTe powder (0.5 g, 99.999%, Alfa Aesar) was used as the source in the upper flow zone while the AAM sample was placed in the second zone. The base pressure was stabilized at 19 mTorr. Both the sample and the source zones were heated at the same time to 400° C. and 650° C., respectively. The growth lasted for 50 min followed by a cool down.

### Top Contact Fabrication

The as-deposited CdTe film was ion milled (1 kV Ar+ and 80 degree incident angle) for 10 min to obtain a flat surface for the ease of top contact fabrication. It was then soaked in a CdCl₂ solution in methanol (12 g/l) at 60° C. for 20 min, followed by a thermal annealing for 5 min at 370° C. The annealing was carried out at 760 Torr with 200 sccm dry air co-flowing with 200 sccm N₂. Next, the substrate was loaded into a thermal evaporator for the deposition of 1/13 nm Cu/Au bilayer as the top contact electrode.

### Bonding of the Modules on Glass or PDMS

A thin copper wire was bonded to the top contact of the solar cell device with silver paste. Then the substrate was attached to a glass slide with epoxy glue (Double bubble, Hardman Inc.). For the mechanically flexible modules, instead of glass, PDMS was used for the encapsulation. To encapsulate the modules with PDMS, silicone elastomer (Sylgard 184, Dow Corning Corp.) was mixed with the curing agent (10:1 weight ratio) at room temperature, then poured onto the module in a plastic dish to form a ˜2 mm layer, and cured at 60° C. for 6 hrs. The Al substrate was then etched from the back side in a saturated HgCl₂ solution with high selectivity over AAM, CdS NPL array, top contact, and PDMS. The back side of the substrate was subjected to a brief ion mill treatment (1 kV neutralized Ar⁺, 80 degree incident angle with a water cooling chuck) for 5˜10 min. A ˜200 nm indium layer was then thermally evaporated on the back side of the substrate to electrically contact the CdS NPLs. Finally a ˜2 mm thick PDMS was cured on the back side of the substrate to finish the encapsulation process.

### Roll-to-Roll Fabrication Process

An important component for the realization of low-cost flexible photovoltaic systems is the development of an associated technology for low-cost fabrication of transparent contacts and bus bars. In particular, given the very large material utilization associated with large-area photovoltaic systems, it is necessary to realize low-cost materials and appropriate deposition techniques to realize the same. In general, printing is a very promising technique for realization of contacts and bus bars, since it allows for low cost per unit area, and reduced material utilization through the use of additive processing; compared to conventional lithographic techniques with result in substantial material wastage through patterning followed by subsequent etching (i.e., subtractive processing), printing dramatically impacts overall material utilization. In that regard, gravure and ink-jet printing can be utilized to print the top contact layer and the bus bars by using previously developed processes. In gravure printing, a metal cylinder with wells etched to create relief patterns is inked with a material to be printed. A doctor blade is used to wipe the ink from the field regions, leaving ink only in the wells. The inked cylinder then rolls on a flexible substrate, transferring the ink pattern to the same. The ink is then dried/cured to produce a thin, uniform film. Indeed, to maximize efficiency of optical capture in top-contacted photovoltaic applications, it is desirable to minimize the size of the bus bars, since these block light absorption. The gravure printing resolution can be pushed to dimensions as small as 10 μm.

In addition to printing bus bars, printing of the transparent conductor layer can be achieved. Printing and sintering of transparent semiconductor nanoparticles (specifically, ZnO for transparent electronics applications) have already been demonstrated. ZnO and SnO are particularly interesting for PV applications as a transparent conductor for several reasons. First, they offer performance on par or better than conventional indium tin oxide in terms of both transparency and conductivity. Second, it is printable to form high-quality films at low temperatures, compatible with low-cost plastic substrates. Third, and perhaps most importantly, the cost of ZnO and SnO is inherently lower than the cost of ITO, since it is not affected by the vagaries and rapidly increasing price of Indium.

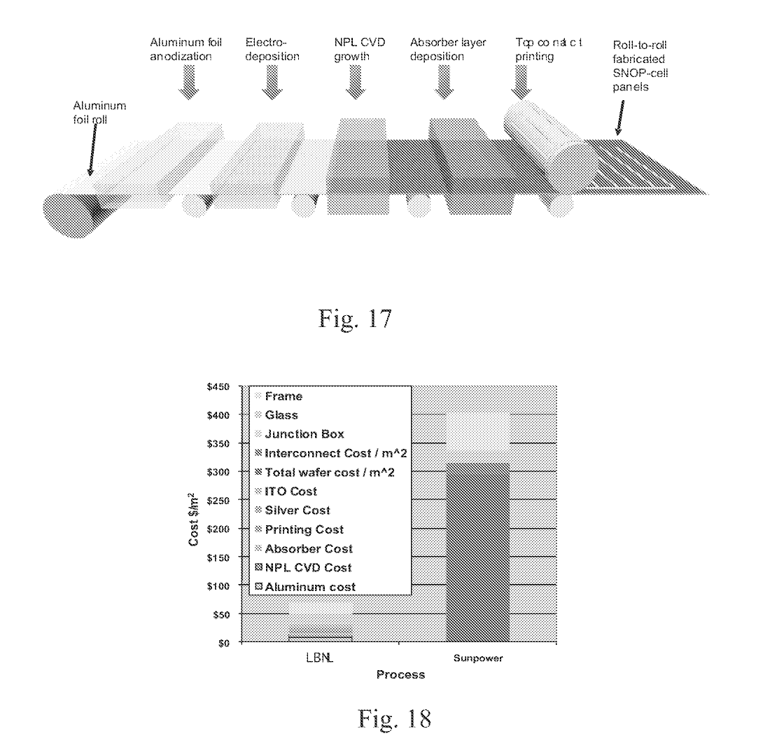

Besides the top contact and bus bars printing, the entire fabrication steps of SNOP-cells could potentially be compatible with a roll-to-roll process. Specifically, anodization of the thin aluminum foil, electroplating of Au catalytic seeds, and chemical vapor deposition growth of the NPLs can all be done by a roll-to-roll process as schematically illustrated in FIG. 17. In fact, both anodization and chemical vapor deposition have been shown in the past to be compatible with roll-to-roll processes for other applications. We envision a similar approach for our technology for enabling large-scale synthesis of single crystalline nanopillar arrays on aluminum foils. This proposed roll-to-roll printing process for fabrication of crystalline nanopillar solar cells could potentially enable high performance modules at low cost.

Of particular interest to cost-effective solar cells needed for mass deployment is exploration of novel device structures for potentially relaxing the materials quality requirements while enabling acceptable efficiencies. In this regard, our described roll-to-roll printed nanopillar-cell technology enables the realization of high performance PV cells at significantly lower cost when compared to the Si technology. Based on a detailed cost-of-goods-sold (COGS) analysis, we are able to include all the major costs associated with the production of panels based on the technology proposed here, including the cost of substrate, precious metals, NPL growth and absorber deposition, and top contact and bus bars. Additionally, the costs of tool depreciation (calculated from known tool costs from both the PV and the LCD industries), labor, and raw materials were included. Costs of research and associated business are not included. From a cost sensitivity analysis (FIG. 18), the most important cost is that of the aluminum foil substrate. The next highest costs are associated with the silver bus bars and the transparent top contacts. The cost of NPL CVD is low, primarily because of the extremely rapid NPL growth rates (1-10 μm/min), and the relatively thin film thickness (˜1 μm).

To facilitate a fair comparison, known costs of the conventional silicon PV panels from SunPower are contrasted to COGS analysis for our process, as shown in the FIG. 18. Clearly, our technology provides 5-6X cost reductions when compared with SunPower technology. Additionally, since the weight of our system is dramatically reduced due to the use of lightweight support substrates, there will be a corresponding reduction in the installation cost, which is not included here. This is a significant benefit given that installation cost is up to 40% of the overall PV deployment cost. Overall, there are clear advantages of the technology proposed herein that can lead to revolutionary and transformative changes in the solar cell industry and the energy sector in general by lowering the cost of PV technology without sacrificing performance.

### Supplementary Information

### Transmission Spectrum of the Cu/Au Top Contact (FIG. 11)

The transmission spectrum of Cu/Au ( 1/13 nm) thin films on a glass substrate was measured by a grating-based spectrometer (SP2360, Princeton Instruments). The sample was illuminated by a high-power halogen lamp using a condenser lens, and the transmitted light through the electrode was collected by a 10× objective. The transmission spectrum of a bare glass substrate was also collected and used for the background correction. The measurement result shown below suggests an average T˜50% transmissions for the give wavelength range, which is significantly lower than that of high quality indium-tin-oxide transparent conductive oxide (T˜85%).

### Crystal Structure and Pptical Property of CdS Nanopillars (FIG. 12)

To characterize the crystal structure of the grown CdS NPLs, an AAM substrate with CdS NPL grown inside was etched fully for ˜1.5 hours in 1 N NaOH. Then the substrate was ultra-sonicated in ethanol to disperse the NPLs into the solution. The NPL suspension was dropped onto a copper grid. Then the crystal structure of the NPLs was characterized with a transmission electron microscope (TEM) (JEM-2100F), which was operated at 200 kV, with a point-to-point resolution of 0.17 nm. As shown in FIGS. 12a and 12b, CdS NPLs are single crystalline with preferred [110] growth direction. FIG. 12c shows the energy dispersive x-ray spectroscopy (EDS) taken from the center part of NPL, revealing that the atomic compositions of Cd and S are 51% and 49%, respectively. FIG. 12d shows the room temperature photoluminescence (PL) of a single CdS NPL measured by exciting the NPL with a He-Cd laser (8 mW of power at 325 nm wavelength, IK series from Kimmon. The measured spectrum demonstrates a peak intensity at ˜500 nm, corresponding to ˜2.4 eV band-to-band emission from CdS.

### Temperature Dependency of the SNOP-Cell Performance (FIG. 14)

Temperature dependent cell performance measurements were performed under ambient conditions. The device was gradually heated up from 297K to 333K, during which dark and light I-V curves were acquired at various temperatures (Fig. S7). To reduce additional heating caused by illumination from the solar simulator, 0.2 sun (20 mW/cm²) intensity was used for the measurements.

### Simulation of the Performance of SNOP-Cells and Planar Cells (FIGS. 15 and 16)

The conversion efficiencies of the SNOP-cell with varying NPL embedded length in CdTe, H, was simulated by using Sentaurus. Since the goal of the simulation is to qualitatively verify the trend of experimental data shown in FIG. 6b instead of obtaining precise cell performance characteristics, the electrodes are assumed to be transparent to both photon and charge carriers. The materials properties of this simulation are summarized in Table 1. The carrier life times for CdTe were purposely chosen to be smaller than that of CdS since the CdS NPLs are single crystalline while the CdTe films are polycrystalline. The Shockley-Read-Hall (SRH) model was chosen as the primary recombination mechanism.

TABLE 1
Materials parameters used for modeling

| Property | CdTe | CdS |
|---|---|---|
| E_{g} (eV) | 1.5 | 2.4 |
| τₑ (ns) | 0.1 | 2.5 |
| τₕ (ns) | 0.1 | 2.5 |
| μₕ (cm²V⁻¹s⁻¹) | 40 | 25¹ |
| μₑ (cm²V⁻¹s⁻¹) | 100 | 100¹ |
| N (cm⁻³) | 1 × 10¹⁶ | 5 × 10¹⁶ |

The simulation results shown in FIGS. 6b and 6d suggest that it is beneficial to have CdS NPLs extend into the CdTe film as much as possible to maximize the carrier collection efficiency. However, due to the processing limitations, a maximum ˜640 nm was utilized in the experiments, which corresponds to ˜6% efficiency extracted from the simulation result shown in FIG. 6b with a CdTe thickness of 1 μm. Additional simulation results using the same material parameters but with a CdTe thickness of 700 nm show a conversion efficiency of ˜12% (results not shown), which suggests a potential direction to improve cell efficiency with even less CdTe material.

To further explore the optimal NPL dimensions, the SNOP-cell performance was simulated as a function of the NPL radius while keeping the NPL pitch constant at 500 nm. As shown in FIG. 15, the maximum efficiency was obtained with ˜100 nm NPL diameter, which corresponds to the actual NPL dimension used in our experiments. The smaller NPL radius results in reduced carrier collection region. On the other hand, the NPL radius of >100 nm results in a loss of CdTe filling factor, which effectively lowers the absorption efficiency.

In order to compare the performance of the SNOP-cell with conventional planar structured CdS/CdTe cell, further simulations were carried out based on the structures shown in FIGS. 16a and 16b in which the material parameters are adopted from Table 1, except that the minority carrier diffusion length, Lₙ is varied from 50 nm to 50 μm. FIG. 16c shows the efficiencies of SNOP and planar cells as a function of Lₙ. It is evident that the SNOP-cell is superior to the planar cell due to the improved carrier collection, especially when Lₙ is smaller than the device thickness (2 μm).

As used herein and in the appended claims, the singular forms “a”, “and”, and “the” include plural referents unless the context clearly dictates otherwise.

The foregoing detailed description of the present invention is provided for the purposes of illustration and is not intended to be exhaustive or to limit the invention to the embodiments disclosed. Accordingly, the scope of the present invention is defined by the appended claims.

### REFERENCES

1. Law, M., Greene, L. E., Johnson, J. C., Saykally, R. & Yang, P. D. Nanowire dye-sensitized solar cells. Nature Mater. 4, 455-459 (2005).
2. Garnett, E. C. & Yang, P. D. Silicon nanowire radial p-n junction solar cells. J. Am. Chem. Soc. 130, 9224-9225 (2008).
3. Czaban, J. A., Thompson, D. A. & LaPierre, R. R. GaAs Core-Shell Nanowires for Photovoltaic Applications. Nano Lett. 9, 148-154 (2009).
4. Tsakalakos, L. et al. Silicon nanowire solar cells. Appl. Phys. Lett. 91 (2007).
5. Kelzenberg, M. D. et al. Photovoltaic measurements in single-nanowire silicon solar cells. Nano Letters 8, 710-714 (2008).
6. Kayes, B. M., Atwater, H. A. & Lewis, N. S. Comparison of the device physics principles of planar and radial p-n junction nanorod solar cells. J. Appl. Phys. 97, 114302 (2005).
7. Spurgeon, J. M., Atwater, H. A. & Lewis, N. S. A comparison between the behavior of nanorod array and planar Cd(Se, Te) photoelectrodes. Journal of Physical Chemistry C 112, 6186-6193 (2008).
8. Fan, Z. Y. et al. Electrical and photoconductive properties of vertical ZnO nanowires in high density arrays. Appl. Phys. Lett. 89, 213110 (2006).
9. Masuda, H. et al. Highly ordered nanochannel-array architecture in anodic alumina. Appl. Phys. Lett. 71, 2770-2772 (1997).
10. Mikulskas, I., Juodkazis, S., Tomasiunas, R. & Dumas, J. G. Aluminum oxide photonic crystals grown by a new hybrid method. Adv Mater 13, 1574-1577 (2001).
11. Marsillac, S., Parikh, V. Y. & Compaan, A. D. Ultra-thin bifacial CdTe solar cell. Solar Energy Mater. Solar Cells 91, 1398-1402 (2007).

What is claimed is:

1. A nanostructure comprising:
a conductive substrate;
an insulating layer on the conductive substrate, the insulating layer comprising an array of pore channels;
metal nanoparticles at bottoms of the pore channels; and
elongated single crystal nanostructures that contacts the metal nanoparticles and that extend out of the pore channels.

2. The nanostructure of claim 1 wherein each of the pore channels has a single metal nanoparticle.

3. The nanostructure of claim 2 wherein the single metal nanoparticle of each of the pore channels conductively couples to the conductive substrate.

4. The nanostructure of claim 1 wherein each of the pore channels has a single elongated nanostructure.

5. The nanostructure of claim 1 wherein the conductive substrate comprises aluminum.

6. The nanostructure of claim 5 wherein the insulating layer comprises aluminum oxide.

7. The nanostructure of claim 1 wherein the metal nanoparticle comprise a transition metal.

8. The nanostructure of claim 7 wherein the transition metal is Au.

9. The nanostructure of claim 1 wherein the elongated single crystal nanostructure comprise a semiconductor.

10. The nanostructure of claim 1 wherein the elongated single crystal nanostructure has a circular cross section.

11. The nanostructure of claim 10 wherein the cross sectional dimension of the elongated single crystal nanostructure changes along its length.

12. The nanostructure of claim 11 wherein the elongated single crystal nanostructure has a dual diameter.

13. The nanostructure of claim 12 wherein the elongated single crystal nanostructure has a larger diameter at its base and a smaller diameter at its end.

14. The nanostructure of claim 1 wherein the elongated single crystal nanostructure has a non-circular cross section.

15. The nanostructure of claim 14 wherein the non circular cross section is selected from the group comprising oval, triangular, diamond, square, and rectangular.

16. The nanostructure of claim 1 wherein a portion of that portion of the nano pillar that extends out of the pore channels is coated with a photo absorber layer.

17. The nanostructure of claim 1 wherein the photo absorber layer comprises CdTe.

18. The nanostructure of claim 9 wherein the semiconductor comprises CdS.

19. A photovoltaic device comprising:
layers in order:
a conductive layer;
an insulating layer; and
a photoabsorption layer;
elongated single crystal nanostructures arranged in an array with axes of the elongated nanostructures perpendicular to a surface of the conductive layer, the elongated nanostructures extending from the insulating layer and into the photoabsorption layer; and
metal nanoparticles conductively coupling the elongated nanostructures to the conductive layer.

20. The photovoltaic device of claim 19 wherein the conductive layer comprises aluminum.

21. The photovoltaic device of claim 19 wherein the insulating layer comprises aluminum oxide.

22. The photovoltaic device of claim 19 wherein the elongated nanostructures comprise nanopillars.

23. The photovoltaic device of claim 19 wherein the array of the elongated nanostructures comprises a regular array of the elongated nanostructures.

24. The photovoltaic device of claim 19 wherein each of the elongated nanostructures comprises a semiconductor.

25. The photovoltaic device of claim 24 wherein the semiconductor comprises CdS.

26. The photovoltaic device of claim 19 wherein the photoabsorption layer comprises CdTe.

27. The photovoltaic device of claim 19 further comprising an at least semi-transparent conductive layer coupled to the photoabsorption layer.

28. The photovoltaic device of claim 19 further comprising a flexible layer coupled to the conductive layer.

29. The photovoltaic device of claim 19 further comprising an at least semi-transparent flexible layer coupled to the at least semi-transparent conductive layer.

30. A method of fabricating a nanostructure comprising:
forming an insulating layer on a conductive substrate, the insulating layer having pore channels arranged in an array;
forming metal nanoparticles in the pore channels, the metal nanoparticles conductively coupling to the conductive layer;
forming elongated single crystal nanostructures in the pore channels; and
etching away a portion of the insulating layer which leaves the elongated single crystal nanostructures extending out of the insulating layer, thereby forming protruding elongated single crystal nanostructures.

31. The method of claim 30 wherein forming the insulating layer on the conductive substrate comprises forming an anodic alumina membrane on an aluminum substrate.

32. The method of claim 31 wherein the aluminum substrate comprises aluminum foil.

33. The method of claim 31 further comprising performing a barrier etch of bottoms of the pore channels prior to forming the metal nanoparticles in the pore channels, the barrier etch leaving at most a thin layer of alumina at bottoms of the pore channels.

34. The method of claim 30 wherein the metal nanoparticles comprises a transition metal.

35. The method of claim 34 wherein the transition metal is Au.

36. The method of claim 34 wherein the transition metal is in liquid form during the formation step of the elongated single crystal nanostructure.

37. The method of claim 30 wherein the elongated single crystal nanostructures comprise nanopillars.

38. The method of claim 30 wherein the elongated single crystal nanostructures comprise CdS.

39. The method of claim 30 further comprising forming a photoabsorption layer on the insulating layer that covers the protruding elongated single crystal nanostructures, thereby forming a photovoltaic device.

40. The method of claim 39 wherein the photoabsorption layer comprises CdTe.

41. The method of claim 40 further comprising the forming an at least semi-transparent conductive layer on the photoabsorption layer.

42. The method of claim 40 further comprising the encapsulating the photovoltaic device within a flexible material.
